(19) United States
(12) Patent Application Publication
(10) Pub. No.: US 2025/0329621 A1
(43) Pub. Date: Oct. 23, 2025

(54) SEMICONDUCTOR DEVICE PACKAGE

(71) Applicant: Advanced Semiconductor Engineering Korea, Inc., Paju-Si (KR)

(72) Inventors: Sangchul HYUN, Paju-Si (KR); Jahwi BAE, Paju-Si (KR); Dongwon LEE, Paju-Si (KR)

(73) Assignee: Advanced Semiconductor Engineering Korea, Inc., Paju-Si (KR)

(21) Appl. No.: 18/642,741

(22) Filed: Apr. 22, 2024

(51) Int. Cl. H01L 23/495; H01L 23/31

(52) U.S. Cl. CPC H01L 23/49582; H01L 23/3107; H01L 23/49541

(57) ABSTRACT

A semiconductor device package is provided. The semiconductor device package includes a plurality of leads, an encapsulant, and a solder element. The plurality of leads includes a first lead. The encapsulant is disposed at two sides of the first lead. The solder element is disposed over a top surface of the first lead. In a cross-sectional view perspective, the first lead and the encapsulant collectively define a space tapering in a first direction from the top surface toward a lower surface of the first lead, and the space is configured to direct the solder element to flow from the top surface along a first lateral surface of the first lead toward a bottom portion of the space.

### BACKGROUND

### 1. Technical Field

The present disclosure relates generally to a semiconductor device package.

### 2. Description of the Related Art

Wettable flanks can be used to improve the soldering performance of QFNs (quad flat package no-leads), and to reduce inspection costs through optical inspection after soldering. Wettable flanks can also improve the soldering quality of QFNs, which can meet the criterion of the soldering quality by visual observation.

However, existing wettable flank-QFNs (WF-QFN) have a structural weakness with respect to burr defects resulting from the cutting operations for the wettable flanks. Because of the ductile property of leads in the QFNs, a portion of the leads may be gradually lengthened during cutting operations and become burr defects, which may cause a short defect between the leads, and make it difficult to achieve mass production.

### SUMMARY

In one or more arrangements, a semiconductor device package includes a plurality of leads, an encapsulant, and a solder element. The plurality of leads includes a first lead. The encapsulant is disposed at two sides of the first lead. The solder element is disposed over a top surface of the first lead. In a cross-sectional view perspective, the first lead and the encapsulant collectively define a space tapering in a first direction from the top surface toward a lower surface of the first lead, and the space is configured to direct the solder element to flow from the top surface along a first lateral surface of the first lead toward a bottom portion of the space.

In one or more arrangements, a semiconductor device package includes a plurality of leads and a first barrier portion. The plurality of leads includes a first lead having a first lateral surface and a second lateral surface opposite to the first lateral surface. The first barrier portion is disposed between the leads and spaced apart from the first lateral surface and the second lateral surface respectively by a first gap and a second gap configured to accommodate a solder element, wherein the first gap has a first width, and the second gap has a second width the first width.

In one or more arrangements, a semiconductor device package includes a plurality of leads and an encapsulant. The plurality of leads includes a first lead. The encapsulant includes a first portion and a second portion spaced apart from the first portion, wherein the first portion and the second portion are disposed between the leads and are spaced apart from the leads respectively by a first gap and a second gap. The first lead includes a first burr extending into the first gap and a second burr extending into the second gap, and an area of the first burr is different from an area of the second burr in a cross-sectional view perspective.

### BRIEF DESCRIPTION OF THE DRAWINGS

Aspects of the present disclosure are better understood from the following detailed description when read with the accompanying drawings. It is noted that various features may not be drawn to scale, and the dimensions of the various features may be arbitrarily increased or reduced for clarity of discussion.

FIG. 1 is a perspective view of a semiconductor device package in accordance with some arrangements of the present disclosure.

FIG. 1A is a perspective view of a portion of a semiconductor device package in accordance with some arrangements of the present disclosure.

FIG. 1B is a perspective view of a portion of a semiconductor device package in accordance with some arrangements of the present disclosure.

FIG. 1C is a perspective view of a portion of a semiconductor device package in accordance with some arrangements of the present disclosure.

FIG. 2A is a perspective view of a portion of a semiconductor device package in accordance with some arrangements of the present disclosure.

FIG. 2B is a perspective view of a portion of a semiconductor device package in accordance with some arrangements of the present disclosure.

FIG. 2C is a perspective view of a portion of a semiconductor device package in accordance with some arrangements of the present disclosure.

FIG. 3A is a top view of a portion of a semiconductor device package in accordance with some arrangements of the present disclosure.

FIG. 3B is a top view of a portion of a semiconductor device package in accordance with some arrangements of the present disclosure.

FIG. 3C is a cross-section of a portion of a semiconductor device package in accordance with some arrangements of the present disclosure.

FIG. 3D is a cross-section of a portion of a semiconductor device package in accordance with some arrangements of the present disclosure.

FIG. 4A illustrates a scanning electron microscopic image of a portion of a semiconductor device package according to some embodiments of the present disclosure.

FIG. 4B illustrates a scanning electron microscopic image of a portion of a semiconductor device package according to some embodiments of the present disclosure.

FIG. 5, FIG. 5A, FIG. 5B, FIG. 6, FIG. 6A, FIG. 6B, FIG. 7, FIG. 7A, and FIG. 7B, illustrate various stages of an exemplary method for manufacturing a semiconductor device package in accordance with some embodiments of the present disclosure.

Common reference numerals are used throughout the drawings and the detailed description to indicate the same or similar elements. The present disclosure will be more apparent from the following detailed description taken in conjunction with the accompanying drawings.

### DETAILED DESCRIPTION

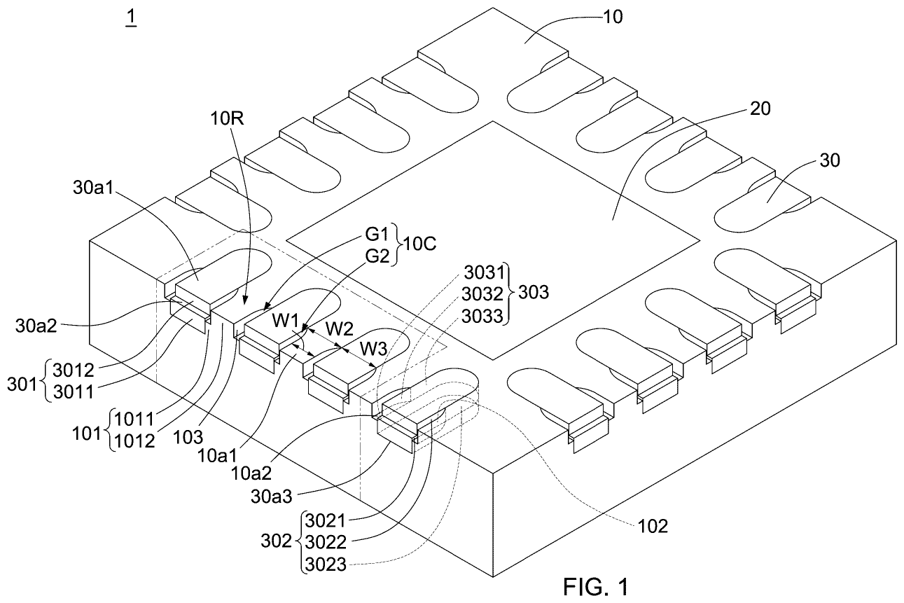

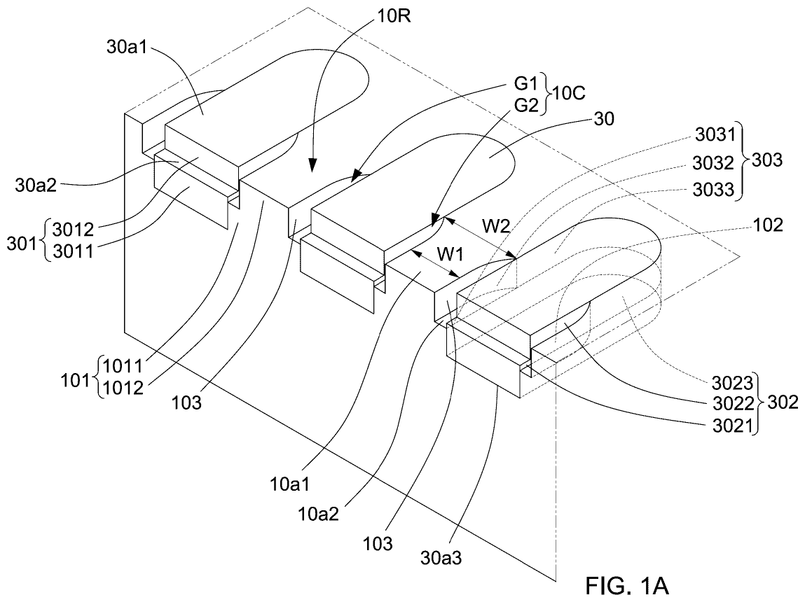

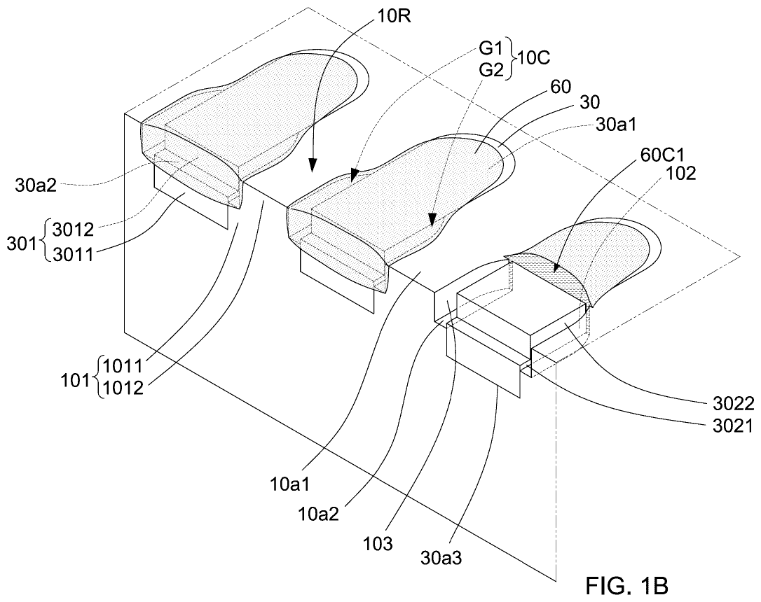

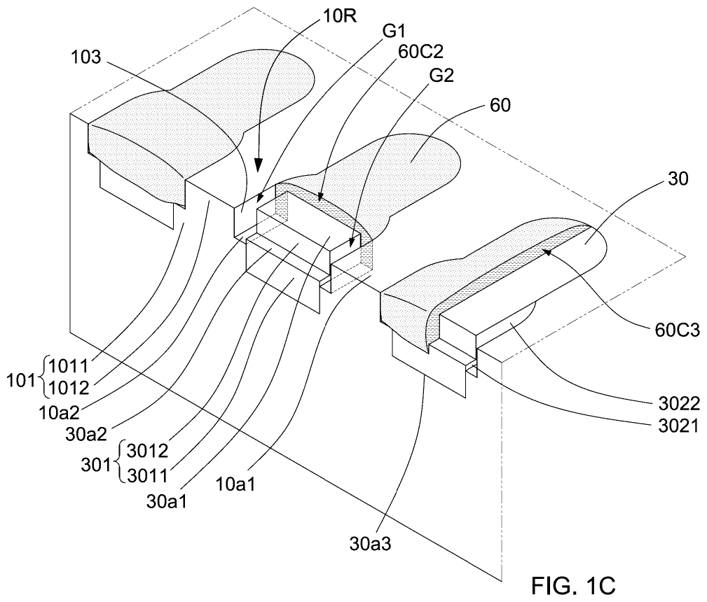

FIG. 1 is a perspective view of a semiconductor device package 1 in accordance with some arrangements of the present disclosure. FIG. 1A is a perspective view of a portion of a semiconductor device package 1 in accordance with some arrangements of the present disclosure. FIG. 1B is a perspective view of a portion of a semiconductor device package 1 in accordance with some arrangements of the present disclosure. The semiconductor device package 1 may include an encapsulant 10, a die paddle 20, a plurality of leads 30, and solder elements 60. Please be noted that the solder elements 60 are omitted in FIG. 1 and FIG. 1A for clarity. The structures illustrated in FIG. 1 and FIG. 1A may include the solder elements 60 as shown in FIG. 1B.

The encapsulant 10 may encapsulate the die paddle 20 and the leads 30. The encapsulant 10 may have a surface 10a1 (also referred to as “an upper surface” of “a top surface”) and a surface 101 (also referred to as “a lateral surface,” “a side surface,” or “a side”) connected to the surface 10a1. In some arrangements, the surface 101 is facing away from a center region of the semiconductor device package 1. The encapsulant 10 may include an insulating material or a dielectric material. The encapsulant 10 may be made of or include a molding material that may include, for example, a Novolac-based resin, an epoxy-based resin, a silicone-based resin, or other suitable encapsulant materials. Suitable fillers may also be included, such as powdered SiO₂. In some arrangements, the encapsulant 10 includes an epoxy resin, a molding compound (e.g., an epoxy molding compound or other molding compound), polyimide, a phenolic compound or material, a material including a silicone dispersed therein, or a combination thereof.

In some arrangements, the encapsulant 10 has or defines a plurality of cavities 10C (also referred to as “recesses” or “trenches”). The encapsulant 10 may further have surfaces 102 and 103 (also referred to as “lateral surfaces,” “side surfaces,” or “sides”) and surfaces 10a2 (also referred to as “upper surfaces” of the encapsulant 10) connected to the surfaces 102 and 103. In some arrangements, each of the cavities 10C is defined by the surfaces 102 and 103 and the surface 10a2, and the surface 10a2 is also referred to as the bottom surface of the cavity 10C. In some arrangements, at least one of the leads 30 is partially exposed by or disposed in at least one of the cavities 10C. The encapsulant 10 may be disposed at two sides of at least one of the leads 30.

In some arrangements, the encapsulant 10 includes barrier portions 10R. The barrier portions 10R may be referred to as tapered portions or separating walls. In some arrangements, each of the barrier portions 10R may be defined by two cavities 10C. In some arrangements, the barrier portions 10R are disposed between the leads 30. In some arrangements, the leads 30 are disposed between the barrier portions 10R. The barrier portion 10R may be configured to function as a safe wall to prevent lead-to-lead short circuit.

In some arrangements, the barrier portion 10R has a side surface or an end surface (e.g., the surface 101) facing away from a center region of the semiconductor device package 1. In some arrangements, the side surface or the end surface (e.g., the surface 101) of the barrier portion 10R tapers toward the surface 10a1 of the encapsulant 10. In some arrangements, the side surface or the end surface (e.g., the surface 101) of the barrier portion 10R includes an upper part 1011 and a lower part 1012 wider than the upper part 1011, and the upper part 1011 has the top surface (e.g., the surface 10a1) of the encapsulant 10. In some arrangements, a roughness of the surface 101 is greater than a roughness of the surface 10a1. In some arrangements, the surface 101 and the surface 10a1 of the encapsulant 10 are generated by two different techniques, resulting in different roughnesses of the surfaces.

In some arrangements, the barrier portion 10R further has a top surface (e.g., the surface 10a1) connected to the surface 101. In some arrangements, the top surface (e.g., the surface 10a1) of the barrier portion 10R tapers toward the surface 101. In some arrangements, the barrier portion 10R includes a first part contacting the leads 30 and a second part spaced apart from the leads 30, and a width W2 of the first part is greater than a width W1 of the second part. In some arrangements, the second part of the barrier portion 10R having the width W1 has the side surface or the end surface (e.g., the surface 101). In some arrangements, the side surface or the end surface (e.g., the surface 101) of the barrier portion 10R tapers toward the top surface (e.g., the surface 10a1) of the barrier portion 10R. In some arrangements, the side surface or the end surface (e.g., the surface 101) of the barrier portion 10R includes an upper part 1011 and a lower part 1012 wider than the upper part 1011, and the upper part 1011 has the top surface (e.g., the surface 10a1) of the barrier portion 10R.

In some arrangements, the barrier portion 10R further has side surfaces or lateral surfaces (e.g., the surfaces 102 and 103) facing the leads 30. In some arrangements, a roughness of the surface 101 is less than a roughness of the surface 102. In some arrangements, a roughness of the surface 101 is less than a roughness of the surface 103. In some arrangements, a roughness of the surface 101 is greater than a roughness of the surface 10a1. In some arrangements, the surface 102 includes a curved surface. In some arrangements, the surface 103 includes a curved surface. In some arrangements, the surface 101 and the surfaces 102 and 103 of the encapsulant 10 are generated by two different techniques, resulting in different roughnesses of the cut surfaces. In some arrangements, the surface 101 is formed by a mechanical cutting operation, and the surfaces 102 and 103 are formed by an energy-beam ablation operation. The barrier portion 10R may include an organic material, and the heat generated by the energy-beam ablation operation may damage the surfaces 102 and 103 more severely than the mechanical cutting operation does to the surface 101, thus the roughnesses of the surfaces 102 and 103 are greater than the roughness of the surface 101.

The die paddle 20 may be embedded in or encapsulated by the encapsulant 10. The die paddle 20 may be exposed from the surface 10a1 of the encapsulant 10. The die paddle 20 may be disposed in a relatively central region of the encapsulant 10. The die paddle 20 may be separated from the leads 30. The die paddle 20 may be made of or include copper, copper alloy or another suitable metal or metal alloy. In some embodiments, the die paddle 20 may include copper (Cu), Cu alloy, iron (Fe), Fe alloy, nickel (Ni), Ni alloy, or any other suitable metal or metal alloy, or a combination thereof. The die paddle 20 may be configured to, for example, serve as a carrier on which electronic component(s) (not shown) are disposed.

The leads 30 may be embedded in or encapsulated by the encapsulant 10. The leads 30 may be exposed from the surfaces 10a1 and 101 of the encapsulant 10. The leads 30 may be made of or include copper, copper alloy or another suitable metal or metal alloy. In some embodiments, the leads 30 may include Cu, Cu alloy, Fe, Fe alloy, Ni, Ni alloy, or any other suitable metal or metal alloy, or a combination thereof. The leads 30 may serve as solder wettable flanks, which may be used for inspection to ensure the joint quality between the semiconductor device package (such as the semiconductor package structure 1) and other electronic components (such as a motherboard, not shown).

In some arrangements, the lead 30 has surfaces 30a1 and 30a2 (also referred to as “upper surfaces” or “top surfaces”), a surface 30a3 (also referred to as “a bottom surface”), and surfaces 3011 and 3012 (also referred to as “lateral surfaces”). The surface 30a1 may be referred to as a top surface or an upper surface of the lead 30, and the surface 30a2 may be referred to as a lower surface of the lead 30. The surfaces 3011 and 3012 collectively may be referred to as a lateral surface 301 of the lead 30. In some arrangements, the surface 30a1 of the lead 30 is substantially parallel to the top surface (e.g., the surface 10a1) of the encapsulant 10 (or the barrier portion 10R). In some arrangements, the surface 3011 is substantially aligned with the surface 101 of the encapsulant 10. In some arrangements, the end surface (e.g., the surface 101) of the barrier portion 10R is substantially aligned or co-planar with the lateral surface (e.g., the surface 3011) of the lead 30. In some arrangements, the barrier portion 10R is disposed between the leads 30 and tapers toward the surface 3011 of at least one of the leads 30. In some arrangements, the lead 30 includes a wettable flank. In some arrangements, the wettable flank is defined by the surface 3012 and recessed with respect to the surface 101 of the encapsulant 10 (or the barrier portion 10R). In some arrangements, the surface 3012 serves as a wettable flank. In some arrangements, one or more of the barrier portions 10R disposed between the leads 30 may protrude beyond one or more of the wettable flanks (e.g., the surfaces 3012) of one or more of the leads 30. In some arrangements, the lead 30 includes a lower portion having an end surface (e.g., the surface 3011) substantially aligned or co-planar with the surface 101 of the encapsulant 10 (or the barrier portion 10R). In some arrangements, a width W1 of the barrier portion 10R is different from a width W3 of the lead 30.

In some arrangements, the lead 30 separates the cavity 10C into gaps G1 and G2 (also referred to as “cavities” or “sub-cavities”). The lead 30 has a side 303 facing the gap G1 and a side 302 facing the gap G2. The side 302 may be opposite to the side 303. The side 303 may include surfaces 3031, 3032, and 3033, the surface 3031 may be connected to the surface 30a2, the surface 3032 may be connected to the surface 30a1, and the surface 3033 may contact or be covered by the encapsulant 10. The side 302 may include surfaces 3021, 3022, and 3033, the surface 3021 may be connected to the surface 30a2, the surface 3022 may be connected to the surface 30a1, and the surface 3023 may contact or be covered by the encapsulant 10. The surface 3011 may extend between the side 302 and the side 303. In some arrangements, the encapsulant 10 includes portions (e.g., the barrier portions 10R) that are spaced apart from each other and disposed between the leads 30, and the portions (or the barrier portions 10R) are spaced apart from the leads 30 respectively by the gap G1 and the gap G2. The gap G1 may be defined by the surfaces 10a2 and 103 of the encapsulant 10 and the side 303 (or the surfaces 3031 and 3032) of the lead 30. The gap G2 may be defined by the surfaces 10a2 and 102 of the encapsulant 10 and the side 302 (or the surfaces 3021 and 3022) of the lead 30. In some arrangements, the surface 103 defines at least a portion of the gap G1 and includes a curved surface from a top view perspective. In some arrangements, the surface 103 defines a curved shape with the top surface of the barrier portion 10R. In some arrangements, the surface 102 defines at least a portion of the gap G2 and includes a curved surface from a top view perspective. In some arrangements, the barrier portion 10R is spaced apart from the side 303 or the surface 3032 by the gap G1, and the barrier portion 10R is spaced apart from the side 302 or the surface 3022 by the gap G2. In some arrangements, the gaps G1 and G2 are configured to accommodate the solder element 60. In some arrangements, the encapsulant 10 and the leads 30 collectively define one or more spaces (e.g., or the cavities 10C). The cavities 10C (or the gaps G1 and G2) collectively may be referred to as a gap structure. In some arrangements, the space is configured to direct the solder element 60 to flow from the surface 30a1 along one or more lateral surfaces (e.g., surfaces 3012, 3022, and 3032) of the lead 30 toward a bottom portion of the space.

Referring to FIG. 1B, the solder elements (also referred to as “solder balls”) may be disposed over the surfaces 30a1 of the leads 30. In some arrangements, the solder element 60 extends over or along the surfaces 30a1, 3012, and 30a2 of the lead 30. In some arrangements, the solder element 60 further covers at least a portion of the surface 3011 of the lead 30. In some arrangements, the solder element 60 includes portions filled or entirely filled in the gaps G1 and G2. In some arrangements, the solder element 60 contacts the surfaces 10a1, 102, and 103. In some arrangements, the solder element 60 may partially cover the surface 10a1 and the surface 101 of the encapsulant 10. In some arrangements, a portion of the surface 30a1 of the lead 30 may be exposed by the solder element 60. Please be noted that a portion of the right-side solder element 60 is omitted from the drawing to show a cross-section 60C1 of the solder element 60 over the encapsulant 10 and the lead 30.

According to some arrangements of the present disclosure, the barrier portions 10R are protruded beyond the surfaces 3012 of the leads 30, such that no empty spaces connecting or communicating the adjacent leads 30 are formed before the mechanical cutting operation is performed to complete the singulation operation for forming the semiconductor device package 1. As such, residues from the leads 30 formed during the mechanical cutting operation can be prevented from being driven or carried by the saw blade to extend between and connect the adjacent leads 30. Therefore, metal burrs can be blocked from extending between the adjacent leads 30, burr effects can be prevented, and thus short circuit between the leads 30 can be prevented. In view of the above, the pitch of the leads 30 can be further reduced and/or the distribution density of the leads 30 can be further increased with the burr effects being effectively prevented by the barrier portions 10R, and the processing tolerance of the singulation operation can be increased, which can further increase the yield.

In addition, according to some arrangements of the present disclosure, the surface 101 are substantially aligned or co-planar with the surfaces 3011 of the leads 30, residues from the leads 30 originally adhered or stuck to the wheel blade can be scraped off by the surface 101. Therefore, residues from the leads 30 can be effectively removed from the semiconductor device package 1, thus the burr effect can be prevented, and the short circuit between the leads 30 can be prevented accordingly.

Moreover, according to some arrangements of the present disclosure, the gaps G1 and G2 can accommodate more solder materials, and therefore, it may enhance the jointing strength and prevent the short circuit caused by excessive solder materials electrically connecting two adjacent leads 30. Furthermore, according to some arrangements of the present disclosure, the barrier portion 10R (or the surface 10a1) tapers toward the surface 101, and thus the accommodation space provided by the gaps G1 and G2 are enlarged, which is further advantageous to enhancing the jointing strength between the solder materials and the leads 30. In addition, the stepped profiles (e.g., the surfaces 3012 and 30a2) of the leads 30 can may provide a greater area for jointing a conductive layer, e.g., a solder material, thereby increasing the rigidity of the semiconductor device package 1.

FIG. 1C is a perspective view of a portion of a semiconductor device package in accordance with some arrangements of the present disclosure. In some arrangements, FIG. 1C is a perspective view of a portion of the semiconductor device package 1 illustrated in FIG. 1 and FIG. 1A.

In some arrangements, the solder elements 60 are disposed over the surfaces 30a1 of the leads. Please be noted that a portion of the middle solder element 60 is omitted from the drawing to show a cross-section 60C2 of the solder element 60 over the encapsulant 10 and the lead 30, and a portion of the right-side solder element 60 is omitted from the drawing to show a cross-section 60C3 of the solder element 60 over the encapsulant 10 and the lead 30. In some arrangements, the solder element 60 extends over or along the surfaces 30a1, 3012, and 30a2 of the lead 30. In some arrangements, the solder element 60 further covers at least a portion of the surface 3011 of the lead 30. In some arrangements, the solder element 60 includes portions filled or entirely filled in the gaps G1 and G2. In some arrangements, the solder element 60 contacts the surfaces 10a1, 102, and 103. In some arrangements, the solder element 60 is free from contacting the surface 10a1 and the surface 101 of the encapsulant 10. In some arrangements, the solder element 60 covers the surface 30a1 of the lead 30 entirely.

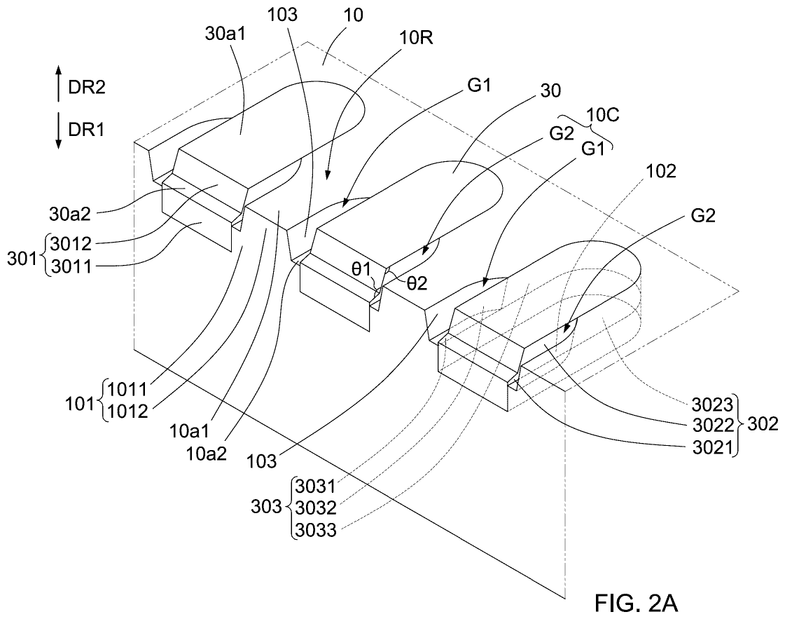

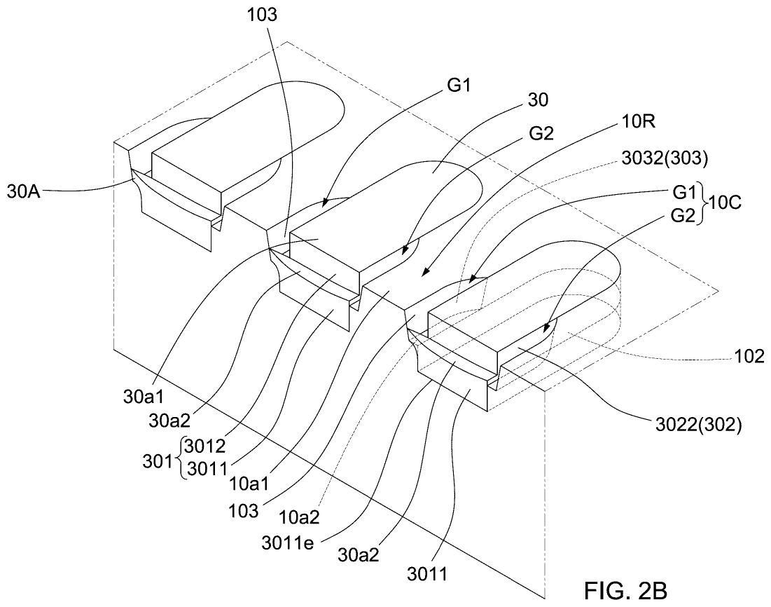

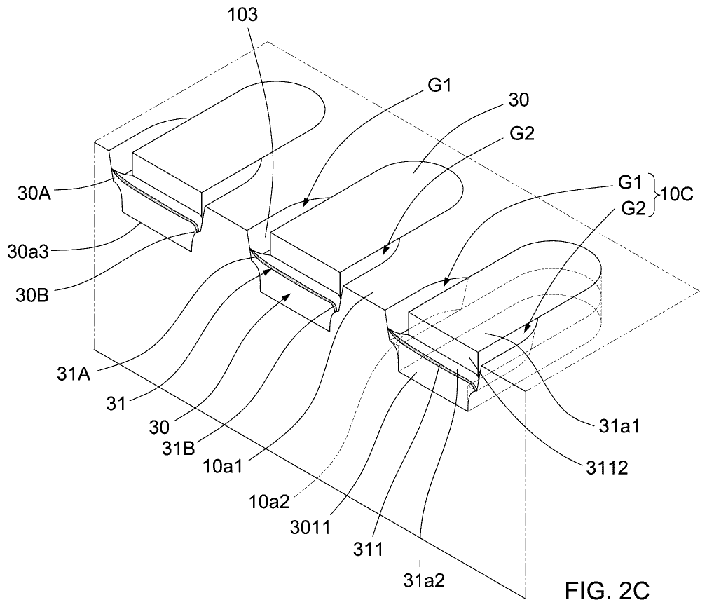

FIG. 2A is a perspective view of a portion of a semiconductor device package in accordance with some arrangements of the present disclosure. The structure illustrated in FIG. 2A is similar to that in FIG. 1A, and the differences therebetween are described as follows. In some arrangements, the structure illustrated in FIG. 2A may be a portion of the semiconductor device package 1 in FIG. 1. Please be noted that the solder elements 60 are omitted in FIG. 2A for clarity. The structures illustrated in FIG. 2A may include the solder elements 60 as shown in FIG. 1B or in FIG. 1C.

In some arrangements, the surface 3012 is inclined with respect to the surface 30a1 of the lead 30. In some arrangements, the surface 30a2 is non-parallel to the surface 30a1 of the lead 30. In some arrangements, the surface 30a2 is inclined with respect to the surface 3011 of the lead 30. In some arrangements, the upper surface (e.g., the surface 30a2) extends between the lateral surface (e.g., the surface 3012) and the lateral surface (e.g., the surface 3011) of the lead 30, and an angle θ1 defined by the lateral surface (e.g., the surface 3012) and the upper surface (e.g., the surface 30a2) is greater than 90 degrees. In some arrangements, an angle θ2 defined by the lateral surface (e.g., the surface 3012) and the top surface (e.g., the surface 30a1) of the lead 30 is greater than 90 degrees. In some arrangements, an angle defined by the lateral surface (e.g., the surface 3011) and the upper surface (e.g., the surface 30a2) of the lead 30 is greater than 90 degrees. In some arrangements, the surfaces 3012 and 30a1 define a stepped slope for contacting or jointing a conductive layer, e.g., a solder material.

In some arrangements, the encapsulant 10 and the leads 30 collectively define one or more spaces (e.g., or the cavities 10C). In some arrangements, the space (or the cavity 10C) tapers in a direction DR1 from the surface 30a1 toward the surface 30a2 of the lead 30. In some arrangements, the space is configured to direct the solder element to flow from the surface 30a1 along one or more lateral surfaces (e.g., surfaces 3012, 3022, and 3032) of the lead 30 toward a bottom portion of the space. In some arrangements, the surface 101 of the encapsulant 10 tapers in a direction DR2 opposite to the direction DR1.

According to some arrangements of the present disclosure, the surfaces 101 of the barrier portions 10R taper toward the surface 10a1, thus the gaps G1 and G2 can accommodate more solder materials, and therefore, it may enhance the jointing strength between the solder materials and the leads 30 and prevent the short circuit caused by excessive solder materials electrically connecting two adjacent leads 30.

In addition, according to some arrangements of the present disclosure, the surfaces 3012 and 30a1 of the leads 30 define a stepped slope for contacting or jointing a conductive layer, e.g., a solder material. Such structure can provide a greater area for jointing the conductive layer, thereby increasing the rigidity of the semiconductor device package.

FIG. 2B is a perspective view of a portion of a semiconductor device package in accordance with some arrangements of the present disclosure. The structure illustrated in FIG. 2B is similar to that in FIG. 1A, and the differences therebetween are described as follows. In some arrangements, the structure illustrated in FIG. 2B may be a portion of the semiconductor device package 1 in FIG. 1. Please be noted that the solder elements 60 are omitted in FIG. 2B for clarity. The structures illustrated in FIG. 2B may include the solder elements 60 as shown in FIG. 1B or in FIG. 1C.

In some arrangements, the lead 30 includes an extension (also referred to as “a lower portion”) having the surface 101 as an end surface and the surface 30a2 as an upper surface. In some arrangements, an elevation of the upper surface (e.g., the surface 30a2) of the extension of the lead 30 increases toward the surface 103 of the encapsulant 10. In some arrangements, an elevation of the upper surface (e.g., the surface 30a2) of the extension of the lead 30 increases toward the gap G1.

In some arrangements, the barrier portion 10R and the side 303 of the lead 30 define the gap G1 (or the cavity), and the extension of the lead 30 is partially disposed in the gap G1 (or the cavity). In some arrangements, the extension of the lead 30 tapers toward the gap G1 (or the cavity). In some arrangements, the extension of the lead 30 further covers a corner portion of the surface 101 adjacent to the gap G1. In some arrangements, the extension of the lead 30 contacts the surface 103 of the encapsulant 10. In some arrangements, a gap G2 (or the cavity) is between the surface 102 of the encapsulant 10 and the side 302 of the lead 30. In some arrangements, the gaps G1 and G2 are on opposite sides of the lead 30. In some arrangements, the extension of the lead 30 is spaced apart from the surface 102 of the encapsulant 10. In some arrangements, an elevation of the upper surface (e.g., the surface 30a2) of the extension of the lead 30 increases toward the gap G1 (or the cavity) with respect to a bottom surface (e.g., the surface 10a2) of the gap G1 (or the cavity).

The cavities 10C (or the gaps G1 and G2) collectively may be referred to as a gap structure. In some arrangements, the lead 30 includes a portion 30A (also referred to as “a burr” or “a protrusion”) extending into the gap G1 (or the gap structure). The extension of the lead 30 may include the portion 30A (or the burr).

FIG. 2C is a perspective view of a portion of a semiconductor device package in accordance with some arrangements of the present disclosure. The structure illustrated in FIG. 2C is similar to that in FIG. 1A, and the differences therebetween are described as follows. In some arrangements, the structure illustrated in FIG. 2C may be a portion of the semiconductor device package 1 in FIG. 1. Please be noted that the solder elements 60 are omitted in FIG. 2C for clarity. The structures illustrated in FIG. 2C may include the solder elements 60 as shown in FIG. 1B or in FIG. 1C.

The cavities 10C (or the gaps G1 and G2) collectively may be referred to as a gap structure. In some arrangements, the lead 30 includes portions 30A (also referred to as “protrusions”) extending into the gaps G1 and G2 (or the gap structure). The extension of the lead 30 may include the portions 30A and 30B (also referred to as “burrs”). In some arrangements, the portion 30A (or the burr) extends into the gap G1, and the portion 30B (or the burr) extends into the gap G2. In some arrangements, an area of the portion 30A (or the burr) is different from an area of the portion 30B (or the burr) in a cross-sectional view perspective. In some arrangements, an elevation of the portion 30A is higher than an elevation of the portion 30B with respect to the surface 10a3 (or the bottom surface) of the lead 30. In some arrangements, two or more of leads 30 may each have portions 30A and 30B, and the portions 30A of the leads 30 extend toward the same direction.

In some arrangements, the semiconductor device package further includes a plating layer 31 over the extension of the lead 30. In some arrangements, the plating layer 31 has a lateral surface 311 substantially aligned or co-planar with the lateral surface (e.g., the surface 3011) of the lead 30. In some arrangements, the plating layer 31 is partially disposed in or extending into the gap G1 (or the cavity). In some arrangements, the plating layer 31 is partially disposed in or extending into the gap G2 (or the cavity). The plating layer 31 may be made of or include tin (Sn), antimony (Sb), silver (Ag), nickel (Ni), palladium (Pd), gold (Au), or a combination thereof. The plating layer 31 may be made of or include a material having a higher solder wettability than that of the leads 30.

In some arrangements, the plating layer 31 covers the lead 30 with the surface 3011 of the lead 30 exposed by the plating layer 31. In some arrangements, an upper surface 31a2 of the plating layer 31 tapers toward the gap G1. In some arrangements, the lateral surface 3112 of the plating layer 31 is recessed with respect to the surface 3011 of the lead 30. In some arrangements, the upper surface 31a1 of the plating layer 31 is substantially aligned with the surface 10a1 of the encapsulant 10 (or the barrier portion 10R). In some arrangements, the plating layer 31 further covers the sides 302 and 303 of the lead 30.

In some arrangements, a roughness of the lateral surface 311 is greater than a roughness of the upper surface 31a2. In some arrangements, a roughness of the lateral surface 311 is greater than a roughness of the lateral surface 3112. In some arrangements, a roughness of the lateral surface 311 is greater than a roughness of the upper surface 31a1. The surface 311 of the plating layer 31 may be formed by a mechanical cutting operation and thus has an increased roughness.

In some arrangements, a roughness of the surface 3011 of the lead 30 is greater than a roughness of the upper surface 31a2 of the plating layer 31. In some arrangements, a roughness of the surface 3011 of the lead 30 is greater than a roughness of the lateral surface 3112 of the plating layer 31. In some arrangements, a roughness of the surface 3011 of the lead 30 is greater than a roughness of the upper surface 31a1 of the plating layer 31. The surface 3011 of the lead 30 may be formed by a mechanical cutting operation and thus has a relatively large roughness compared to that of the surfaces 30a2, 3112, and 31a1.

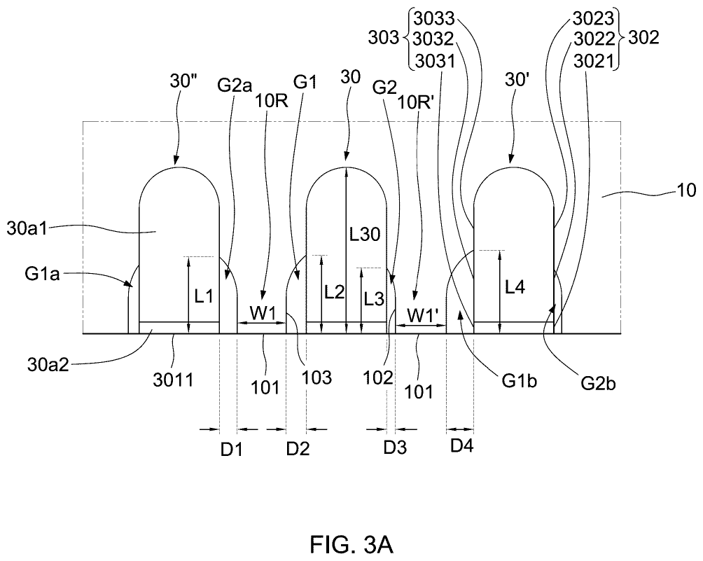

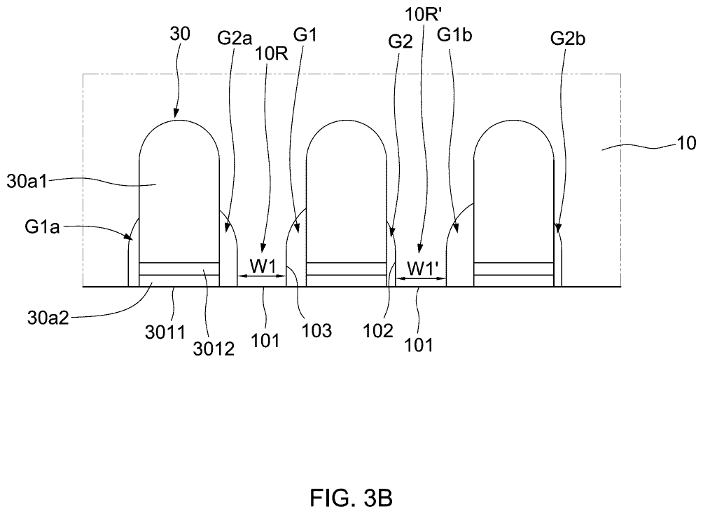

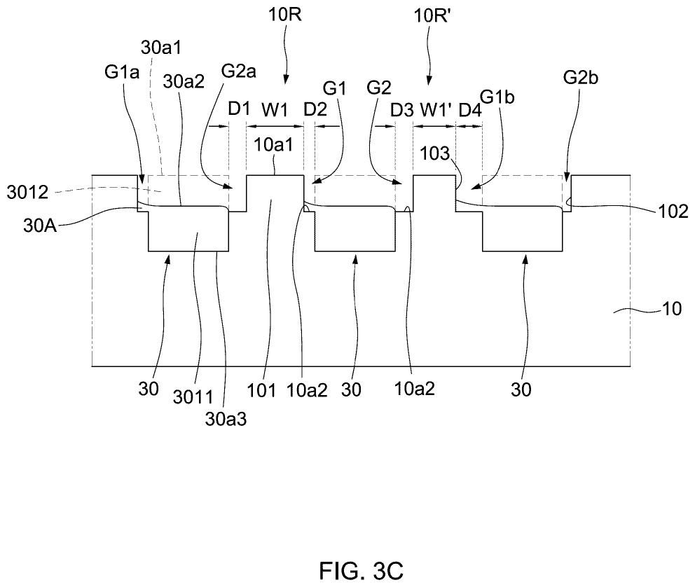

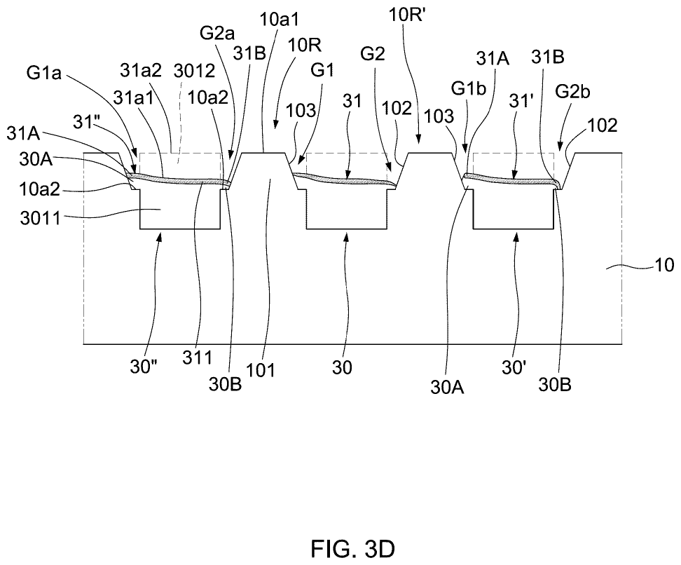

FIG. 3A is a top view of a portion of a semiconductor device package in accordance with some arrangements of the present disclosure. The structure illustrated in FIG. 3A is similar to a portion of the structure illustrated in FIG. 1A, and the differences therebetween are described as follows. In some arrangements, the structure illustrated in FIG. 3A may be a portion of the semiconductor device package 1 in FIG. 1. Please be noted that the solder elements 60 are omitted in FIG. 3A for clarity. The structures illustrated in FIG. 3A may include the solder elements 60 as shown in FIG. 1B or in FIG. 1C.

In some arrangements, the semiconductor device package includes at least leads 30, 30′ and 30″. In some arrangements, the encapsulant 10 includes barrier portions 10R and 10R′ spaced apart from each other. In some arrangements, a width W1 of the barrier portion 10R is different from a width W1′ of the barrier portion 10R′. In some arrangements, the barrier portion 10R is between the leads 30 and 30″, and the barrier portion 10R′ is between the leads 30 and 30′. In some arrangements, the barrier portion 10R (or the second part of the barrier portion 10R) is spaced apart from the lead 30 by a distance D2, and the barrier portion 10R is spaced apart from the lead 30″ by a distance D1 different from the distance D2. In some arrangements, the barrier portion 10R′ (or the second part of the barrier portion 10R′) is spaced apart from the lead 30 by a distance D3, and the barrier portion 10R′ is spaced apart from the lead 30′ by a distance D4 different from the distance D3. In some arrangements, the lead 30 is spaced apart from the barrier portion 10R by the distance D2, and the lead 30 is spaced apart from the barrier portion 10R′ by the distance D3 different from the distance D2. In some arrangements, the distances D1, D2, D3, and D4 may be referred to as the widths of the gaps G2a, G1, G2, and G1b, respectively.

In some arrangements, the side 303 (or the surface 3032) of the lead 30 is exposed to the gap G1 by a length L2, and the side 302 (or the surface 3022) of the lead 30 is exposed to the gap G2 by a length L3 different from the length L2. In some arrangements, the lead 30′ is exposed to the gap G1b by a length L4 different from the length L3. In some arrangements, the lead 30′ is further exposed to the gap G2b by a length different from the length L4. In some arrangements, the lead 30″ is exposed to the gap G2a by a length L1 different from the length L2. In some arrangements, the lead 30″ is further exposed to the gap G1a by a length different from the length L1. In some arrangements, the lengths L1, L2, L3, and L4 may be referred to as the lengths of the gaps G2a, G1, G2, and G1b, respectively. In some arrangements, a length L30 of the lead 30 is greater than at least one of the lengths of the gaps. In some arrangements, the length L30 of the lead 30 is greater than the lengths of the gaps.

In some arrangements, the differences in the lengths L1, L2, L3, and L4 and the differences in the distances D1, D2, D3, and D4 may be resulted from misalignments of the energy-beam ablation areas and the locations of the leads 30.

FIG. 3B is a top view of a portion of a semiconductor device package in accordance with some arrangements of the present disclosure. The structure illustrated in FIG. 3B is similar to the structure illustrated in FIG. 3A, and the differences therebetween are described as follows. In some arrangements, the structure illustrated in FIG. 3B may be a portion of the semiconductor device package 1 in FIG. 1. Please be noted that the solder elements 60 are omitted in FIG. 3B for clarity. The structures illustrated in FIG. 3B may include the solder elements 60 as shown in FIG. 1B or in FIG. 1C.

In some arrangements, referring to FIG. 2A, the surface 3012 is inclined with respect to the surface 30a1 of the lead 30.

FIG. 3C is a cross-section of a portion of a semiconductor device package in accordance with some arrangements of the present disclosure. The structure illustrated in FIG. 3C is similar to a portion of the structure illustrated in FIG. 1A, and the differences therebetween are described as follows. In some arrangements, the structure illustrated in FIG. 3C may be a portion of the semiconductor device package 1 in FIG. 1. Please be noted that the solder elements 60 are omitted in FIG. 3C for clarity. The structures illustrated in FIG. 3C may include the solder elements 60 as shown in FIG. 1B or in FIG. 1C.

In some arrangements, the extensions of the leads 30 are partially disposed in the gaps G1, G1a, and G1b, respectively. In some arrangements, the extensions of the leads 30 taper toward the gaps G1, G1a, and G1b, respectively. In some arrangements, the extensions of the leads 30 are spaced apart from the surfaces 102 of the encapsulant 10. In some arrangements, an elevation of an upper surface (e.g., the surface 30a2) of at least one of the extensions of the leads 30 increases toward the gaps G1, G1a, and/or G1b with respect to the bottom surface (e.g., the surface 10a2) of the gaps G1, G1a, and/or G1b.

FIG. 3D is a cross-section of a portion of a semiconductor device package in accordance with some arrangements of the present disclosure. The structure illustrated in FIG. 3D is similar to the structure illustrated in FIG. 3C, and the differences therebetween are described as follows. In some arrangements, the structure illustrated in FIG. 3D may be a portion of the semiconductor device package 1 in FIG. 1. Please be noted that the solder elements 60 are omitted in FIG. 3D for clarity. The structures illustrated in FIG. 3D may include the solder elements 60 as shown in FIG. 1B or in FIG. 1C.

In some arrangements, the semiconductor device package further includes plating layers 31, 31′, and 31″ over the extensions of the leads 30, 30′ and 30″, respectively. In some arrangements, the plating layer 31 tapers toward the surface 102 and the surface 103 of the encapsulant 10 in a cross-sectional view perspective. In some arrangements, the plating layer 31 includes portions 31A and 31B extending into the gaps G1 and G2. In some arrangements, the plating layer 31′ is partially disposed in the gap G1b and spaced apart from the surface 103 by a portion of the lead 30′. In some arrangements, the plating layer 31′ includes portions 31A and 31B extending into the gaps G1b and G2b. In some arrangements, the plating layer 31′ contacts the bottom surface of the gap G2b. In some arrangements, the plating layer 31″ contacts the surfaces 102 and 103 of the encapsulant 10. In some arrangements, the plating layer 31″ includes portions 31A and 31B extending into the gaps G1a and G2a.

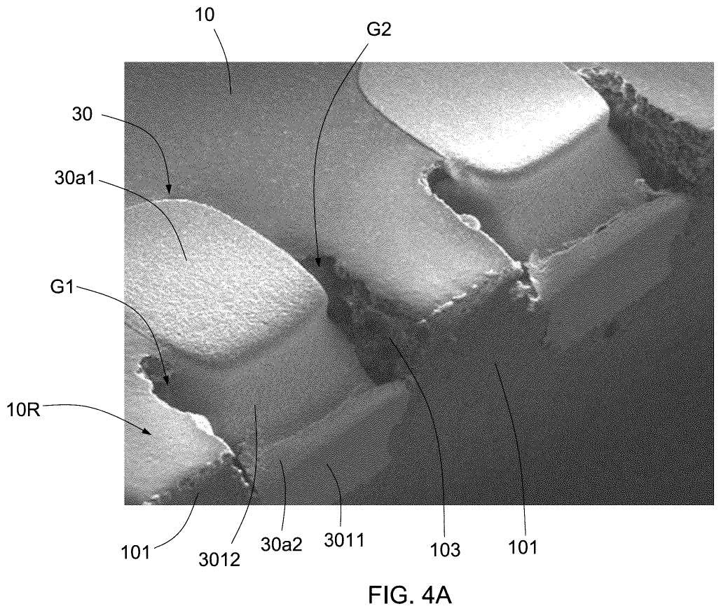

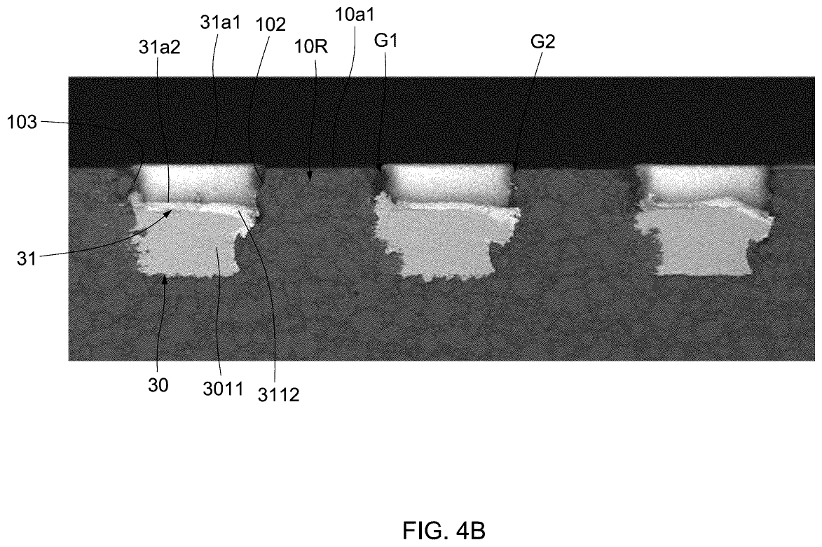

FIG. 4A illustrates a scanning electron microscopic image of a portion of a semiconductor device package according to some embodiments of the present disclosure. In some arrangements, the structure illustrated in FIG. 4A may be a portion of the semiconductor device package 1 in FIG. 1. Please be noted that the solder elements 60 are omitted in FIG. 4A for clarity. The structures illustrated in FIG. 4A may include the solder elements 60 as shown in FIG. 1B or in FIG. 1C.

In some arrangements, the lead 30 has an upper portion protruding beyond the surface 3012. The upper portion may include the surface 30a1 as a top surface. In some arrangements, the surfaces 3012 and 30a2 are inclined surfaces that are non-perpendicular to the surface 30a1. In some arrangements, the surface 30a2 has a non-uniform width. In some arrangements, the surface 103 and the surface 102 (not shown in FIG. 4A) of the encapsulant 10 are rough surfaces

FIG. 4B illustrates a scanning electron microscopic image of a portion of a semiconductor device package according to some embodiments of the present disclosure. In some arrangements, the structure illustrated in FIG. 4B may be a portion of the semiconductor device package 1 in FIG. 1. Please be noted that the solder elements 60 are omitted in FIG. 4A for clarity. The structures illustrated in FIG. 4A may include the solder elements 60 as shown in FIG. 1B or in FIG. 1C.

In some arrangements, a portion of the lead 30 is exposed by the plating layer 31 and protruding upwards in the gap G1. In some arrangements, a portion of the plating layer 31 is disposed in the gap G2. In some arrangements, the plating layer 31 has a non-uniform thickness.

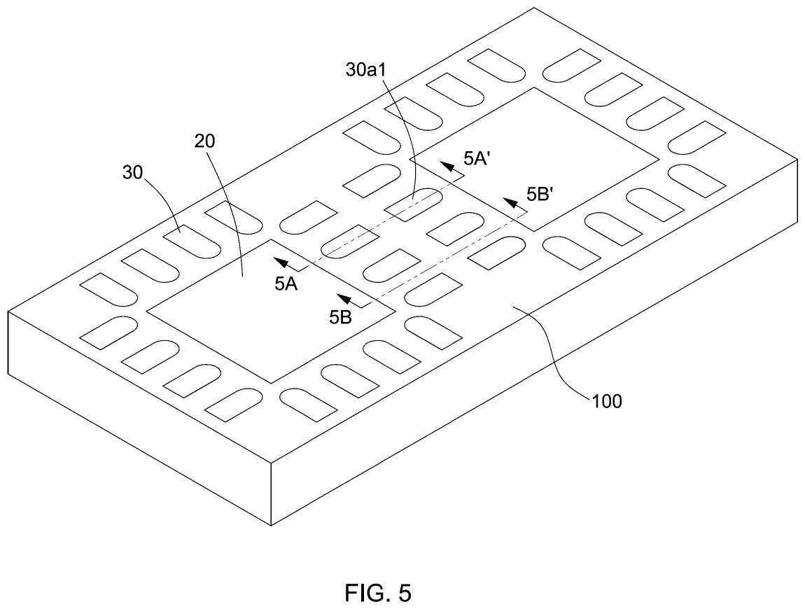

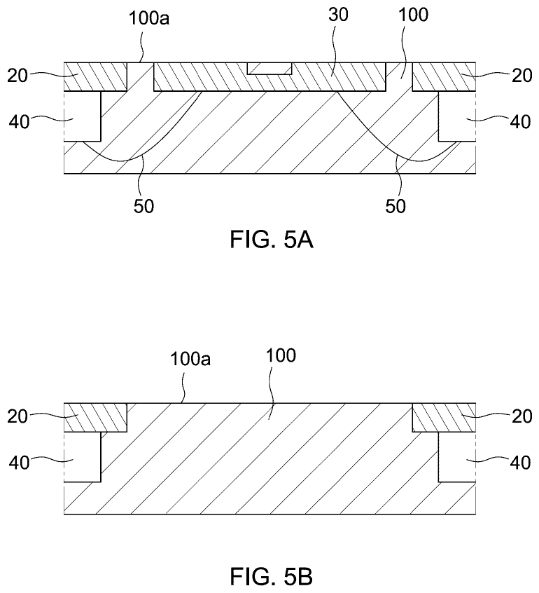

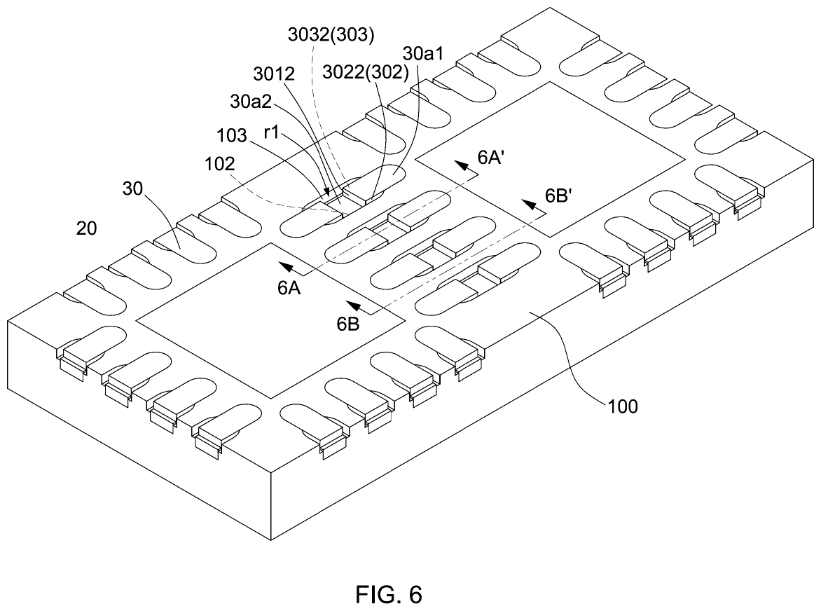

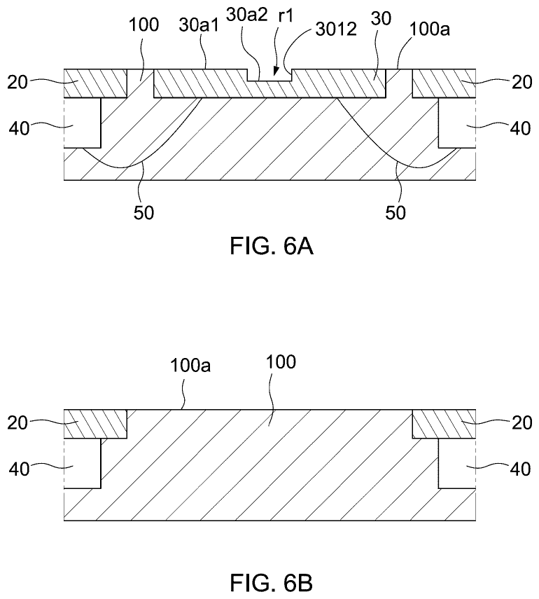

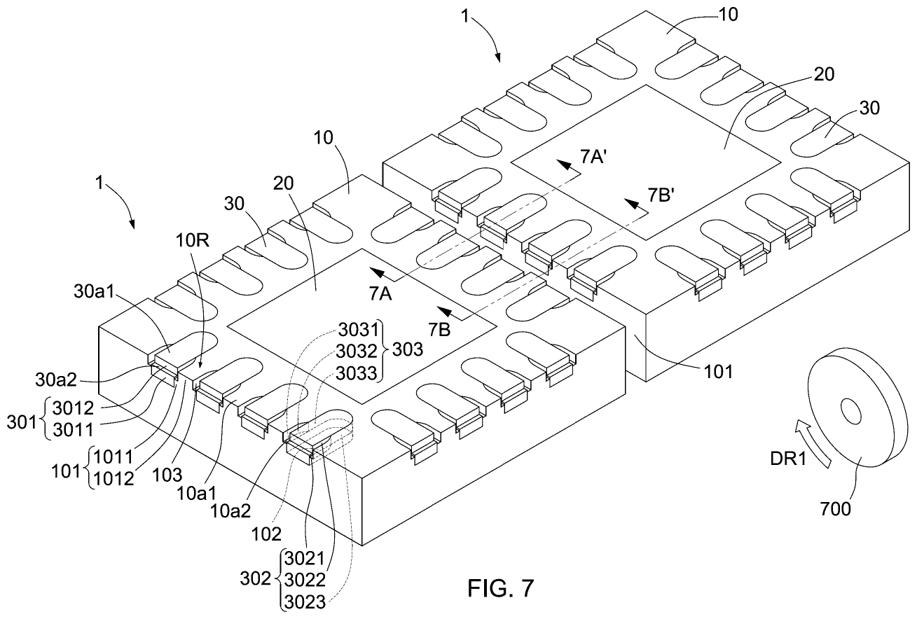

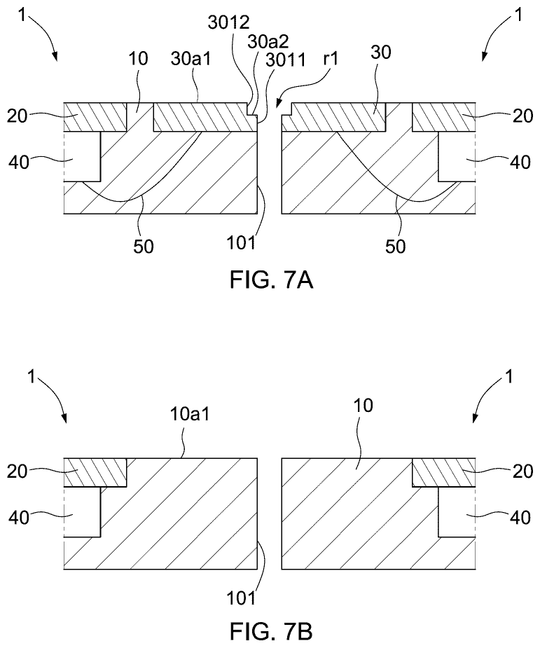

FIG. 5, FIG. 5A, FIG. 5B, FIG. 6, FIG. 6A, FIG. 6B, FIG. 7, FIG. 7A, and FIG. 7B, illustrate various stages of an exemplary method for manufacturing a semiconductor device package in accordance with some embodiments of the present disclosure.

Referring to FIG. 5, a package structure including two or more semiconductor device package units that are not separated may be provided. Each of the semiconductor device package units may include a die paddle 20 and a plurality of leads 30. The package structure may include an encapsulating material 100 encapsulating the die paddles 20 and the leads 30. In some arrangements, surfaces 30a1 (or the top surfaces) of the leads 30 are exposed by the encapsulating material 100.

Referring to FIG. 5A and FIG. 5B, FIG. 5A is a cross-section along a line 5A-5A′ in FIG. 5, and FIG. 5B is a cross-section along a line 5B-5B′ in FIG. 5. The semiconductor device package unit may include a semiconductor device 40 and a plurality of bonding wires 50. The semiconductor device 40 may be disposed on the die paddle 20. The semiconductor device 40 may include integrated circuits (ICs). The bonding wires 50 may be disposed on the semiconductor device 40. The bonding wires 50 may be configured to electrically connect the semiconductor device 40 and the leads 30. The bonding wires 50 may include or be made of one or more metal materials, such as copper (Cu), silver (Ag), aluminum (Al), gold (Au), or an alloy thereof. The encapsulating material 100 may cover the semiconductor device 40 and the bonding wires 50. The die paddle 20 and the leads 30 may be exposed by an upper surface 100a of the encapsulating material 100.

Referring to FIG. 6, FIG, 6A, and FIG. 6B, FIG. 6A is a cross-section along a line 6A-6A′ in FIG. 6, and FIG. 6B is a cross-section along a line 6B-6B′ in FIG. 6.

A first singulation operation may be performed to half-cut the package structure. In some arrangements, an energy-beam ablation operation is performed to half-cut the package structure from the upper surface 100a of the encapsulating material 100 to form a plurality of recesses r1. The recesses r1 may be formed between two adjacent semiconductor device package units. The recesses r1 may surround a periphery of each of the semiconductor device package units. In some arrangements, the recesses r1 are spaced apart from each other by portions of the encapsulating material 100. In some arrangements, each one or two of the leads 30 are partially exposed by one of the recesses r1. In some arrangements, the recesses r1 expose portions of the leads 30 without connecting or communicating lateral sides (e.g., the sides 302 and 303) of adjacent leads 30. In some arrangements, portions of the upper surface 100a are irradiated to remove portions of the encapsulating material 100 by energy-beams to form the recesses r1. In some arrangements, each of the recesses r1 is formed by an energy-beam. In some arrangements, the recesses r1 are formed one-by-one along the peripheral of each of the semiconductor device package units. In some arrangements, energy-beams are applied on lead areas instead of on a continuous edge area of the semiconductor device package unit. The energy-beam may be a laser beam, for example, an ultraviolet (UV) laser beam, which may have a wavelength of about 200 nm, but is not limited thereto. The species and intensity of the energy-beams may be selected, depending on the materials of the encapsulating material 100 and the leads 30, so that the energy-beams can remove the targeted material(s). In some arrangements, the energy-beams can remove portions of the encapsulating material 100 with no or nearly no damage to the leads 30. After the energy-beam ablation operation is performed, the surfaces 102 and 103 of the encapsulating material 100 are exposed to the recesses r1. In some arrangements, the surfaces 3012, 3022, and 3032 of the leads 30 are exposed to the recesses r1.

The energy-beam ablation operation may have different selectivity on the encapsulating material 100 and the leads 30. As a result, the leads 30 may be partially exposed by the encapsulating material 100. After the energy-beam ablation operation is performed, the lead 30 may have three lateral surfaces (e.g., the surfaces 3012, 3022, and 3032) exposed to the recess r1. The surfaces 102 and 103 of the encapsulating material 100 formed by the energy-beam ablation operation may have a greater roughness. Therefore, the surfaces 102 and 103 of the encapsulant 10 may be rough surfaces as shown in FIG. 4A.

In some arrangements, the energy-beam ablation operation may further remove portions of encapsulating material 100 such that the recess r1 may have a greater depth. In some arrangements, the lateral surfaces (such as the surface 3021 and 3031 shown in FIG. 1A) of the lead 30 may be exposed from the recess r1.

Referring to FIG. 7, FIG, 7A, and FIG. 7B, FIG. 7A is a cross-section along a line 7A-7A′ in FIG. 7, and FIG. 7B is a cross-section along a line 7B-7B′ in FIG. 7.

A second singulation operation may be performed to separate the semiconductor device package units crossing the recesses r1 to form the semiconductor device packages 1. In some arrangements, the second singulation operation may remove portions of the encapsulating material 100 and portions of the leads 30. In some arrangements, the second singulation operation may include a mechanical cutting operation. In some arrangements, the mechanical cutting operation may include cutting the encapsulating material 100 and the leads 30 using a mechanical cutting tool 700, e.g., a saw blade. The mechanical cutting tool 700 may be a cutting wheel, a wheel blade, or the like. After the second singulation operation is performed, the surface 101 (or the lateral surface) of the encapsulant 10 may be formed, and the surfaces 3011 of the leads 30 may be formed and exposed by the surface 101 of the encapsulant 10. A width (or an aperture) of the recess r1 is greater than a width (or a distance) of the gap between the surfaces 101 of the encapsulants 10 of the adjacent semiconductor device packages 1.

In some arrangements, a cutting wheel or a wheel blade is used as the mechanical cutting tool 700 to cut through the package structure crossing the recesses r1 to separate the semiconductor device packages 1. In some arrangements, the mechanical cutting tool 700 (or the wheel blade) cuts through the recesses r1 with a blade rotation in a direction DR1. In some arrangements, referring to FIGS. 1A-2C, gaps G1 and G2 formed from the recesses r1 are spaced apart from each other by the barrier portions 10R of the encapsulant 10 formed by the mechanical cutting tool 700, and residues from the leads 30 formed during the mechanical cutting operation may extend into the gaps G1 and G2, thus the residues from the leads 30 are spaced apart from each other by the barrier portions 10R formed by mechanically cutting the encapsulating material 100 crossing the recesses r1. In some arrangements, referring to FIGS. 2B and 2C, the extension of the leads 30 that is partially disposed in the gap G1 and optionally in the gap G2 may be formed from the residues from the leads 30 and extending into the gaps G1 and G2 during the mechanical cutting operation.

In some arrangements, referring to FIG. 7 and FIG. 2B, when the leads 30 are cut by the mechanical cutting tool 700 (or the wheel blade), due to the ductile nature of the metal materials (e.g., Cu) of the leads 30, metal burrs may be generated and extend in the direction DR1 of the blade rotation. Therefore, the extensions of the leads 30 may include portions formed from the metal burrs and partially filled in the gaps G1, and the portions in the gaps G1 may protrude upwards resulted from the direction DR1 of the blade rotation. In addition, less residues from the leads may be accumulated in the gaps G2 due to the direction DR1 of the blade rotation.

In some arrangements, an electroplating process may be performed to form a plating layer 31 as shown in FIG. 2C on the exposed surface (such as the surfaces 30a1, 3012, 3022, and 3033 as shown in FIG. 6) of the leads 30 before the singulation operation, and the singulation operation further includes cutting the plating layer 31 to form surfaces 311 of the plating layer 31 exposed to the gap resulted from the cutting.

In some arrangements, referring to FIG. 7 and FIG. 2C, when the leads 30 and the plating layers 31 covering the leads 30 are cut by the mechanical cutting tool 700 (or the wheel blade), due to the ductile nature of the metal materials (e.g., Cu) of the leads 30 and the plating layers 31, metal burrs may be generated and extend in the direction DR1 of the blade rotation. Therefore, the extensions of the leads 30 may include portions formed from the metal burrs and partially filled in the gaps G1, and the plating layers 31 may also include portions formed from the metal burrs and partially filled in the gaps G1. In some arrangements, the portions of the leads 30 and the plating layers 31 in the gaps G1 may protrude upwards resulted from the direction DR1 of the blade rotation. In addition, less residues from the leads may be accumulated in the gaps G2 due to the direction DR1 of the blade rotation. In some arrangements, the metal burrs formed from the leads 30 and the plating layers 31 and filled in the gaps G1 protrude upwards, and the metal burrs formed from the leads 30 and the plating layers 31 and filled in the gaps G2 extend downwards.

In some arrangements, solder elements 60 may be disposed or formed on the leads 30.

In some cases where a saw blade is used to perform two singulation operations, the lateral surfaces of the leads may have burr defects (e.g., metal burrs) caused by the residues from the leads that stick to the saw blade, especially during the first singulation operation (i.e., the half-cut operation). For example, when empty spaces are formed between the leads after the first singulation operation (e.g., the half-cut operation), residues from the leads may be further formed during the second singulation operation, and these residues may stick to the saw blade and be driven or carried by the saw blade to further extend into the empty spaces between the adjacent leads. The residues may be referred to as the burr defects that may undesirably connect the adjacent leads and cause short circuit between the leads.

According to some arrangements of the present disclosure, an energy-beam ablation operation is used to replace the first singulation operation to half cut the package structure, such that less residues from the leads 30 may be formed and stick to a saw blade, and thus no burr defects or less burr defects are formed on the lateral surfaces (e.g., the surfaces 3011) of the leads 30.

In addition, according to some arrangements of the present disclosure, a plurality of recesses r1 formed by the first singulation operation to half cut the package structure are spaced apart from each other by portions of the encapsulating material 100, such that no empty spaces connecting the adjacent leads 30 are formed during the first singulation operation. As such, residues from the leads 30 formed during the second singulation operation (e.g., a mechanical cutting operation) can be prevented from being driven or carried by the saw blade to extend between and connect the adjacent leads 30. Therefore, metal burrs can be blocked from extending between the adjacent leads 30, burr effects can be prevented, and thus short circuit between the leads 30 can be prevented. In view of the above, the pitch of the leads 30 can be further reduced and/or the distribution density of the leads 30 can be further increased with the burr effects being effectively prevented by the portions of the encapsulating material 100 formed from the recesses r1, and the processing tolerance of the singulation operation can be increased, which can further increase the yield.

Moreover, according to some arrangements of the present disclosure, the surface 101 of the encapsulating material 100 and the surfaces 3011 of the leads 30 are formed by the same mechanical cutting operation that cuts the encapsulating material 100 crossing the recesses r1, and portions of the surface 101 between the recesses r1 protrude beyond the surfaces 3012 of the leads 30. As such, residues from the leads 30 originally adhered or stuck to the wheel blade can be scraped off by the protruding surface 101. Therefore, residues from the leads 30 can be effectively removed from the semiconductor device package 1, thus the burr effect can be prevented, and the short circuit between the leads 30 can be prevented accordingly.

Furthermore, according to some arrangements of the present disclosure, gaps G1 and G2 formed from the recesses r1 are spaced apart from each other by the barrier portions 10R of the encapsulant 10 formed by the mechanical cutting tool 700. As such, the barrier portions 10R may be configured as safe walls to prevent lead-to-lead short circuits during the singulation operation, and residues from the leads 30 formed during the mechanical cutting operation may extend into the gaps G1 and G2, thus the residues from the leads 30 are spaced apart from each other by the barrier portions 10R formed by mechanically cutting the encapsulating material 100 crossing the recesses r1. Therefore, the burr effect can be prevented, and the short circuit between the leads 30 can be prevented accordingly. In addition, the residues in the gaps G1 and G2 may provide a greater area for jointing a conductive layer, e.g., a solder material, and thus the rigidity of the semiconductor device package can be further enhanced.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, a first numerical value can be deemed to be “substantially” the same or equal to a second numerical value if the first numerical value is within a range of variation of less than or equal to ±10% of the second numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” perpendicular can refer to a range of angular variation relative to 90° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°.

Two surfaces can be deemed to be coplanar or substantially coplanar if a displacement between the two surfaces is no greater than 5 μm, no greater than 2 μm, no greater than 1 μm, or no greater than 0.5 μm. A surface can be deemed to be substantially flat if a displacement between a highest point and a lowest point of the surface is no greater than 5 μm, no greater than 2 μm, no greater than 1 μm, or no greater than 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 104 S/m, such as at least 105 S/m or at least 106 S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. A semiconductor device package, comprising:
a plurality of leads comprising a first lead;
an encapsulant disposed at two sides of the first lead; and
a solder element disposed over a top surface of the first lead;
wherein in a cross-sectional view perspective, the first lead and the encapsulant collectively define a space tapering in a first direction from the top surface toward a lower surface of the first lead, and the space is configured to direct the solder element to flow from the top surface along a first lateral surface of the first lead toward a bottom portion of the space.

2. The semiconductor device package as claimed in claim 1, wherein the encapsulant has a lateral surface tapering in a second direction opposite to the first direction.

3. The semiconductor device package as claimed in claim 2, wherein the first lead further has a second lateral surface substantially co-planar with the lateral surface of the encapsulant.

4. The semiconductor device package as claimed in claim 3, wherein the first lateral surface of the first lead is recessed with respect to the lateral surface of the encapsulant.

5. The semiconductor device package as claimed in claim 1, wherein an angle defined by the first lateral surface and the lower surface of the first lead is greater than 90 degrees.

6. The semiconductor device package as claimed in claim 5, wherein an angle defined by the first lateral surface and the top surface of the first lead is greater than 90 degrees.

7. The semiconductor device package as claimed in claim 6, wherein the solder element extends over the top surface, the first lateral surface, and the lower surface of the first lead.

8. The semiconductor device package as claimed in claim 7, wherein the first lead further has a second lateral surface, the lower surface extends between the first lateral surface and the second lateral surface, and the solder element further covers at least a portion of the second lateral surface of the first lead.

9. A semiconductor device package, comprising:
a plurality of leads comprising a first lead having a first lateral surface and a second lateral surface opposite to the first lateral surface; and
a first barrier portion disposed between the leads and spaced apart from the first lateral surface and the second lateral surface respectively by a first gap and a second gap configured to accommodate a solder element, wherein the first gap has a first width, and the second gap has a second width the first width.

10. The semiconductor device package as claimed in claim 9, further comprising a second barrier portion disposed between the leads and spaced apart from the first barrier portion, wherein a width of the first barrier portion is different from a width of the second barrier portion.

11. The semiconductor device package as claimed in claim 9, wherein the first gap has a first length, and the second gap has a second length different from the first length.

12. The semiconductor device package as claimed in claim 11, wherein a length of the first lead is greater than at least one of the first length and the second length.

13. The semiconductor device package as claimed in claim 9, wherein the first lead further has a third lateral surface extending between the first lateral surface and the second lateral surface, and a top surface of the first barrier portion tapers toward a first lateral surface of the first barrier portion that is substantially co-planar with the third lateral surface of the first lead.

14. The semiconductor device package as claimed in claim 13, wherein the first barrier portion further has a second lateral surface defining at least a portion of the first gap, and the second lateral surface further defines a curved shape with the top surface of the first barrier portion.

15. The semiconductor device package as claimed in claim 14, wherein a roughness of the second lateral surface of the first barrier portion that is facing the first lead is greater than a roughness of the first lateral surface of the first barrier portion.

16. The semiconductor device package as claimed in claim 14, wherein a roughness of the second lateral surface of the first barrier portion that is facing the first lead is greater than a roughness of the top surface of the first barrier portion.

17. A semiconductor device package, comprising:
a plurality of leads comprising a first lead; and
an encapsulant comprising a first portion and a second portion spaced apart from the first portion, wherein the first portion and the second portion are disposed between the leads and are spaced apart from the leads respectively by a first gap and a second gap;
wherein the first lead comprises a first burr extending into the first gap and a second burr extending into the second gap, and an area of the first burr is different from an area of the second burr in a cross-sectional view perspective.

18. The semiconductor device package as claimed in claim 17, wherein an elevation the first burr is higher than an elevation of the second burr with respect to a bottom surface of the first lead.

19. The semiconductor device package as claimed in claim 18, wherein the plurality of leads further comprises a second lead distinct from the first lead, the second lead comprises a third burr and a fourth burr extending into a third gap and a fourth gap respectively, and the first burr of the first lead and the third burr of the second lead extend toward a substantially same direction.

20. The semiconductor device package as claimed in claim 17, further comprising a plating layer over the first lead, and a lateral surface of the plating layer is substantially co-planar with a lateral surface of the first lead.
